(19) United States
(12) Patent Application Publication
(10) Pub. No.: US 2022/0372201 A1
(43) Pub. Date: Nov. 24, 2022

(54) INITIATED CHEMICAL VAPOR DEPOSITION AND STRUCTURATION OF POLYOXYMETHYLENE

(71) Applicant: Drexel University, Philadelphia, PA (US)

(72) Inventors: Kenneth K.S. LAU, Haddonfield, NJ (US); Zhengtao CHEN, Hangzhou (CN)

(73) Assignee: Drexel University, Philadelphia, PA (US)

(21) Appl. No.: 17/759,082

(22) PCT Filed: Feb. 9, 2021
(86) PCT No.: PCT/US2021/017193

§ 371 Date: Jul. 19, 2022

Related U.S. Application Data
(60) Provisional application No. 62/975,866, filed on Feb. 13, 2020.

(51) Int. Cl. C08G 2/10; B05D 1/00; C23C 16/52; C23C 16/455

(52) U.S. Cl. CPC C08G 2/10; B05D 1/60; C23C 16/52; C23C 16/45557

(57) ABSTRACT

This invention relates to a method for synthesizing polyoxymethylene on a substrate. The method includes depositing monomer capable of forming polyoxymethylene by an initiated polymerization reaction and an initiator, via initiated chemical vapor deposition (iCVD) onto a surface of a substrate in an initiated chemical vapor deposition reactor.

### CROSS REFERENCE TO RELATED APPLICATION

This application claims the benefit of U.S. Provisional Application No. 62/975,866, filed on Feb. 13, 2020, the entire disclosure of which is hereby incorporated by reference as if set forth fully herein.

### BACKGROUND OF THE INVENTION

During 1920s, Hermann Staudinger first discovered and heavily studied polyoxymethylene (POM).¹⁻² POM is a very popular diesel fuel additive which can reduce hazardous exhaust.³ POM is also widely used as a substitute for metals and alloys, such as in mechanical gears,⁴ due to its high mechanical strength, and abrasion and fatigue resistance.⁵ One unique aspect of POM is its ability to thermally depolymerize cleanly, which makes it an attractive sacrificial material for making transient electronic devices,⁶ microelectromechanical system (MEMS) and microfluidics.⁷

As the size of devices shrinks, conventional liquid-based polymerization can potentially damage the fragile micro/nanostructures of the devices due to strong liquid surface tension forces. The solvents used during the polymerization can be also hard to remove or leave residues behind. This is due to POM being insoluble in common solvents, thus, liquid processing of POM into films and coatings is challenging. A solvent-free method for synthesizing POM, such as hot filament chemical vapor deposition (HFCVD), has been reported. The polymerization via HFCVD requires extreme conditions, with high filament temperatures (˜700° C.) to decompose the trioxane monomer and the use of liquid nitrogen (<−195° C.) to cool the stage on which the polymer is grown, which may potentially damage fragile substrate materials and structures.⁷

### SUMMARY OF THE INVENTION

Additional details and advantages of the disclosure will be set forth in part in the description which follows, and/or may be learned by practice of the disclosure. The details and advantages of the disclosure may be realized and attained by means of the elements and combinations particularly pointed out in the appended claims. It is to be understood that both the foregoing general description and the following detailed description are exemplary and explanatory only and are not restrictive of the disclosure, as claimed.

The following sentences may be used to description certain embodiments of the disclosure.

1. In a first aspect, the present invention relates to a method for synthesizing polyoxymethylene (POM) on a substrate. The method includes a step of depositing an initiator and a monomer capable of forming polyoxymethylene by an initiated polymerization reaction, via initiated chemical vapor deposition (iCVD), onto a surface of a substrate in an initiated chemical vapor deposition reactor.

2. In the method according to sentence 1, the substrate may be cooled to a temperature below the boiling temperature of the monomer and the initiator to promote deposition of the monomer and initiator on the substrate.

3. In the method according to sentence 2, the substrate may be cooled to a temperature of from about 0° C. to about 50° C., or from about 0° to about 40° C., from about 10° C. to about 35° C. or from about 15° C. to about 25° C.

4. In the method according to any one of sentences 1-3, an internal reactor pressure in the initiated chemical vapor deposition reactor may be from about 0.1 to about 10 torr, as measured using a pressure gauge, e.g. a capacitance manometer, or from about 0.5 to about 5 torr, or from about 1 to about 3 torr.

5. In the method according to any one of sentences 1-4, the depositing step may be carried out at a flow rate of monomer to the initiated chemical vapor deposition reactor of from about 0.1 to about 20 standard cubic centimeter per minute (sccm), or from about 2 to about 15 sccm, or from about 3 to about 10 sccm.

6. In the method according to any one of sentences 1-5, the initiator may be selected from the group consisting of boron trifluoride diethyl etherate, boron trifluoride, and other boron trifluoride complexes, including boron trifluoride complexed with water, phenol, acetic acid, tetrahydrofuran, methanol, propanol, ethylamine, methyl sulfide and dibutyl ether.

7. In the method according to any one of sentences 1-6, the initiator may be heated to a temperature of from 30° C. to 50° C., or from 30° C. to 40° C., or about 35° C. prior to feeding the initiator to the initiated chemical vapor deposition reactor.

8. In the method according to any one of sentences 1-7, the initiator may be fed to the initiated chemical vapor deposition reactor at a flow rate of from about 0.1 to 10 standard cubic centimeter per minute (sccm), or from about 0.5 to 7.5 sccm, or from about 1 to 5 sccm.

9. In the method according to any one of sentences 1- 8, the substrate may be selected from silicon, glass, fabrics, paper, plastics, pharmaceuticals, metals, metal oxides, ionic liquids, and surfaces and devices that comprise one or more of structured, templated, machined, and defined topologies.

10. In the method according to any one of sentences 1- 9, the depositing step may be carried out with one or more heated filaments located in the initiated chemical vapor deposition reactor.

11. In the method according to sentence 10, the one or more filaments may be a phosphor bronze filament wire.

12. In the method according to any one of sentences 10-11, the filament may be heated to a temperature of from about 150° C. to 400° C., or from about 200° C. to about 375° C., or from about 250° C. to about 350° C.

13. In the method according to any one of sentences 1-12, the method may further comprise a step of introducing nitrogen gas into the reactor.

14. In the method according to sentence 13, the nitrogen gas may be introduced into the reactor at a flow rate of from 0.1 sccm to about 2 sccm, or a flow rate of about 1 sccm.

15. In the method according to any one of sentences 1-14, the monomer may be selected from the group consisting of 1,3,5-trioxane, formaldehyde, dioxane, other ring molecules that can form formaldehyde and its oligomers such as larger (CH₂O) ring-containing molecules, and other monomers known for use in polymerization reactions to form polyoxymethylene such as polymers of POM having 2-100 repeating groups in linear or cyclic form, as well as dioxane, trioxane and paraformaldehyde.

16. In the method according to any one of sentences 1-15, the depositing step may be carried out under conditions such that the fractional saturation (Z_{M}) of the 1,3,5-trixoane monomer at the substrate surface is typically between 0.1 to about 1, wherein Z_{M} is defined by the following expression:

$${z}_{M} = \frac{{P}_{M}}{{P}_{M , sat}} ,$$

wherein P_{M} is the partial pressure in the gas phase of the monomer, as calculated based on component flow rates metered through precision needle valves or mass flow controllers and reactor total pressure as measured through a pressure gauge, e.g. a capacitance manometer and P_{M,sat} is the vapor pressure of the monomer at the substrate surface, based on the equilibrium vapor pressure data of the monomer at the substrate temperature as measured by a surface temperature probe, e.g. a contact thermocouple.

17. In the method according to any one of sentences 1-16, the method may further comprise a step of introducing one or more co-reactants selected from water, alcohols, and aldehydes.

18. In the method according to sentence 17, the co-reactant may be methanol. The methanol may be introduced into the reactor at a flow rate of from about 0.1 to about 2 sccm, or about 0.1 to about 1 sccm.

19. In the method according to sentence 17, the co-reactant may be paraformaldehyde. The paraformaldehyde may be heated to 60° C.- 120° C. and fed at a vapor flow rate of from about 0.1 sccm to about 2 sccm, or from about 0.1 sccm to about 2 sccm.

20. In the method according to any one of sentences 1-17, the method may further comprise a step of introducing water as a co-reactant.

### BRIEF DESCRIPTION OF THE DRAWINGS

FIG. 1 shows the proposed initiation reaction mechanism for iCVD polymerization of 1,3,5-trioxane.

FIG. 2 shows Fourier-transform infrared (FTIR) spectra of 1,3,5-trioxane monomer (top), and iCVD POM synthesized with filament heating (run #3; middle) and without filament heating (run #2; bottom).

FIG. 3 shows X-ray Powder Diffraction (XRD) spectra which reveals the hexagonal packing of the trigonal crystal form of iCVD POM.

FIGS. 4A-4B, 4D-4E, and 4G-4H show Scanning Electron Microscopy (SEM) images.

FIGS. 4C, 4F, and 4I show water droplet images of iCVD POM films from run #3 (corresponding to FIGS. 4A-4C), run #4 (corresponding to FIGS. 4G-4I), and run #7 (corresponding to FIGS. 4G-4I). Scale bars are 10 μm for FIGS. 4A, 4D, and 4G and 400 nm for FIGS. 4B, 4E, and 4H.

### DETAILED DESCRIPTION OF THE PREFERRED EMBODIMENTS

To address the challenges associated with POM, the present method introduces an alternative solvent-free approach, initiated chemical vapor deposition (iCVD), for creating POM. iCVD vaporizes liquid precursors, typically monomers and initiators, to directly synthesize solid polymers, like POM, on a variety of substrates. By dispensing with the liquid phase, iCVD overcomes poor wettability and substrate damage often associated with liquid solvents. Additionally, the use of a polymerization initiator can significantly lower the filament temperature (250-350° C.) and offers room temperature surface polymerization, which can allow the use of fragile substrates, including fabrics, paper, plastics, pharmaceutics, metals, metal oxides and ionic liquids.

Prior to deposition, the substrate may be cooled to a temperature to promote deposition of the monomer and initiator on the substrate. The substrate may be cooled to a temperature of from about 0° C. to about 50° C., or from about 0° C. to about 40° C., or from about 10° C. to about 35° C., or from about 15° C. to about 25° C. Suitable examples of substrates may include silicon, glass fabrics, paper, plastics, pharmaceuticals, metal, metal oxides, ionic liquids, and surfaces and devices that comprise one or more of structured, templated, machined, and defined topologies.

Specifically, iCVD relies on the continuous delivery of vaporized initiator and monomer in a low/medium-vacuum chamber (1×10⁻³ to 760 torr), where the initiator is selectively activated by heating by any suitable means, such as by use of an array of heated filaments that are suspended over a cooled substrate of interest that promotes the adsorption of activated initiator and monomer, which then leads to the surface polymerization.⁸⁻⁹ Although free radical polymerization has been successfully used to synthesize a diverse number of polymers by iCVD, cationic ring-opening polymerization has proven to be useful in the synthesis of polyethylene oxide (PEO)¹⁰ and polyglycidol (PGL)¹¹ by using ethylene oxide and ethylene glycol monomers, respectively, and the cationic initiator boron trifluoride diethyl etherate (BF₃·O(C₂H₅)₂)

The internal reactor pressure in the initiated chemical vapor deposition reactor may be from about 0.01 to about 100 torr, or from about 0.1 to about 10 torr, or from about 0.5 to about 5 torr, or from about 1 to about 3 torr, as measured using a pressure gauge, e.g. capacitance manometer.

In the present invention, iCVD may be used to synthesize polyoxymethylene (POM) using any suitable combination of monomer and initiator. Suitable monomers are those that are known for use in polymerization reactions to produce POM, such as 1,3,5-trioxane monomer, formaldehyde, dioxane, larger (CH₂O) ring-containing monomers that can form formaldehyde and its oligomers in the iCVD reactor and other suitable monomers for making POM via initiated polymerization. The depositing step may be carried out at a flow rate of monomer to the initiated chemical vapor deposition reactor of from about 0.1 to about 20 standard cubic centimeter per minute (sccm), or from about 2 to about 15 sccm, or from about 3 to about 10 sccm.

In some embodiments, the depositing step is carried out under conditions such that the fractional saturation (Z_{M}) of the 1,3,5-trioxane monomer at the substrate surface is from 0.1 to about 1, wherein Z_{M} is defined by the following expression:

$${z}_{M} = \frac{{P}_{M}}{{P}_{M , sat}} ,$$

wherein P_{M} is the partial pressure of the monomer in the gas phase, as calculated based on component flow rates metered through precision needle valves or mass flow controllers and reactor total pressure as measured through a pressure gauge, e.g. a capacitance manometer and P_{M,sat} is the vapor pressure of the monomer at the substrate surface, based on the equilibrium vapor pressure data of the monomer at the substrate temperature as measured by a surface temperature probe, e.g. a contact thermocouple. P_{M} can be estimated using the formula P_{M}=yₘ*P=(Fₘ/Fₜₒₜ)*P, where yₘ is the mole fraction of monomer in the gas phase and P is the total reactor pressure as measured by a pressure gauge. The yₘ can be calculated based on the ratio of the molar flow rate of monomer to the total molar flow rate (Fₘ/Fₜₒₜ), these flow rates being obtained from flow calibration measurements. P_{M,sat} is the vapor pressure or saturation pressure of the monomer at the substrate surface and is estimated based on thermodynamic relationships, e.g. Antoine or van't Hoff equations, of equilibrium pressure data with temperature from published literature.

Suitable initiators are those known for use in polymerization of monomers to produce POM and particularly preferred initiators are initiators that enable cationic ring opening polymerization reactions using monomers containing one or more cyclic rings. Suitable initiators include, but are not limited to, Lewis acids such as boron trifluoride diethyl etherate, boron trifluoride, and other boron trifluoride complexes, including boron trifluoride complexed with water, phenol, acetic acid, tetrahydrofuran, methanol, propanol, ethylamine, methyl sulfide, and dibutyl ether, other metal halides such as AlCl₃, AlBr₃, TiCl₄, SnCl₄, as well as their organometallic variants like RAlCl₂, R₂AlCl and R₃Cl, where R is an alkyl or aryl group. The initiator may be heated to a temperature of from about 28° C. to about 50° C., or from about 30° C. to 50° C., or from 30° C. to 40° C., or about 35° C. prior to feeding the initiator to the initiated chemical vapor deposition reactor. The initiator may be fed to the initiated chemical vapor deposition reactor at a flow rate of from about 0.05 to 10 standard cubic centimeter per minute (sccm), or from about 0.1 sccm to about 10 sccm, or from about 0.5 to 7.5 sccm, or from about 1 to 5 sccm.

In some embodiments, the depositing step is carried out with one or more heated filaments located in the initiated chemical vapor deposition reactor. Suitable examples of the one or more filaments may be selected from phosphor bronze, copper, beryllium copper, nickel, Chromaloy™, Nichrome, stainless steel, iron and and other suitable metal or metal alloy filament wires. The one or more filament may be heated to a temperature of from about 150° C. to about 400° C., or from about 200° C. to about 375° C., or from about 250° C. to about 350° C. In some embodiments, the method may further comprise a step of introducing nitrogen gas into the reactor. Preferably, the nitrogen gas is introduced into the reactor at a flow rate of from about 0.1 sccm to about 2 sccm, or a flow rate of about 1 sccm.

For example, using 1,3,5-trioxane monomer and boron trifluoride diethyl etherate (BF₃·O(C₂H₅)₂) initiator, a POM polymer film can be made via iCVD. iCVD is used to enable the cationic ring opening polymerization of trioxane monomer in the presence of boron trifluoride initiator to synthesize POM. The iCVD processing conditions can be controlled to influence iCVD polymerization kinetics through one single key parameter, the fractional saturation of monomer at the substrate surface (z=P_{M}/P_{M,sat}), that essentially measures the surface monomer concentration. This z parameter is influenced directly by chemical precursor flow rates, inert carrier gas flow rate, total pressure of the vacuum chamber, filament temperature, and substrate temperature. By controlling the iCVD syn deposition conditions, POM can be successfully grown at conditions that provide high surface monomer concentration. Also, the iCVD synthesis leads to the formation of predominantly the extended crystal chain form of POM in the hexagonal packing of a trigonal crystal structure. The crystallization of POM during iCVD growth leads to structuration of POM films. The resulting structured POM shifts the wettability from a hydrophilic surface for dense POM to a hydrophobic surface for structured POM.

In some embodiments, the method may include a step of introducing one or more co-reactants selected from water, alcohols, and aldehydes, and mixtures thereof. Suitable examples of alcohols may include methanol, ethanol, isopropanol, 1-butanol, 1-hexanol, 1-decanol, propane-2ol, ethanediol, 1,2-propanediol, alkoxy alcohol, alkyl alcohol, preferably methanol is employed. Suitable examples of aldehydes may include formaldehyde, paraformaldehyde, trioxane, acetaldehyde, glyoxal, glutaraldehyde, polyoxymethylene, propionaldehyde, isobutyraldehyde, benzaldehyde. Preferably, the aldehyde is paraformaldehyde.

In embodiments where an alcohol is employed as the co-reactant, the alcohol may be introduced into the reactor at a flow rate of from about 0.1 to about 2 sccm, or about 0.1 to about 1 sccm. In other embodiments, where an aldehyde is employed as the co-reactant, for example, if the aldehyde is paraformaldehyde, the paraformaldehyde is heated to 60° C.- 120° C. to achieve a vapor flow rate of from about 0.1 sccm to about 2 sccm, or from about 0.1 sccm to about 2 sccm.

1. Experimental Section

iCVD setup. A custom-built iCVD reactor, 21×21×4 cm³ in size with a 2.5-cm thick quartz window cover, was used to grow the POM. The substrates were silicon wafers (100 mm in diameter, Pure Wafer), and were placed on the reactor stage that was cooled by backside contact with a thermal fluid flowing through a recirculating chiller (Polyscience 912) to control the substrate temperature between 0° C. and 25° C. A K-type thermocouple was attached to the top surface of the substrates to measure the temperature. A HeNe laser was used to monitor the in-situ growth of polymer film on the substrate. Unique to the POM synthesis, polymer growth could be initiated with and without the present of a heated filament. If the filament was used, a set of 12 phosphor bronze filament wires (0.5 mm diameter, Goodfellow) was placed 2 cm above the substrate. In order to heat the filament up to ˜330° C., the wires were connected to a DC power supply (Vol Teq) set to a constant voltage of 10.5V (4 A). An Edwards rotary vacuum pump (E2M30), a Baratron capacitance manometer (MKS 626C), and a downstream throttle valve (MKS 153D) were used to automatically maintain a set pressure between 1 and 3 torr inside the reactor chamber.

Synthesis. Boron trifluoride diethyl etherate ((BF₃·O(C₂H₅)₂), 98+%, Alfa Aesar) and 1,3,5-trioxane (99.5+%, Acros Organics) were used as the cationic initiator and the monomer, respectively, without further purification. The initiator was heated to 35° C. to achieve enough vapor head pressure. The initiator flow rate was set between 0.1 and 2 sccm (standard cubic centimeter per minute) via a precision needle valve (Swagelok). The monomer was heated to 40° C., using a separate precision needle valve (Swagelok), and the monomer flow rate was set between 3 and 10 sccm. Nitrogen carrier gas (0-2 sccm) was controlled by an automatic mass flow controller (MKS 1479A). The initiator, monomer, and nitrogen were delivered to the reactor via heated 0.25 in. diameter stainless steel tubing. In some reactions, methanol or paraformaldehyde were additionally used as co-reactants. Methanol flow rate was set between 0.1 and 1 sccm, while paraformaldehyde was thermally heated to 60-120 ° C. to achieve a formaldehyde vapor flow rate between 0.1 and 1 sccm.

Characterization. To elucidate polymer chemical structure, FTIR measurements were performed using a Nicolet 6700 from 400-4000 cm⁻¹ at 4 cm⁻¹ resolution over 128 scans. To probe polymer crystallinity, X-ray diffraction (XRD) was performed on a Rigaku SmartLab X-ray diffractometer with a Cu Ka radiation (1.54 Å) with a step size of 0.02°. Scanning electron microscopy (SEM) was used to physically characterize surface morphology. To prepare for SEM analysis, the samples were coated with Pt/Pd using a sputter coater (Cressington 208 HR) at 40 mA for 30 s to minimize charging of the insulating polymer. The samples were positioned in the sputter coater at an angle of 45°, and they were rotated continuously to ensure the samples were evenly coated on the top and the cross-section. SEM was performed on a Zeiss Supra 50 VP with an accelerating voltage at 2-4 kV and a working distance of ˜5 mm. Top-down and cross-sectional views of the substrate were obtained. The wettability of the substrate surfaces was characterized by measuring the contact angle of several test liquids on a contact angle goniometer (ramé-hart instrument co.) and processed by DROPimage Advanced software.

### 2. Results and Discussion

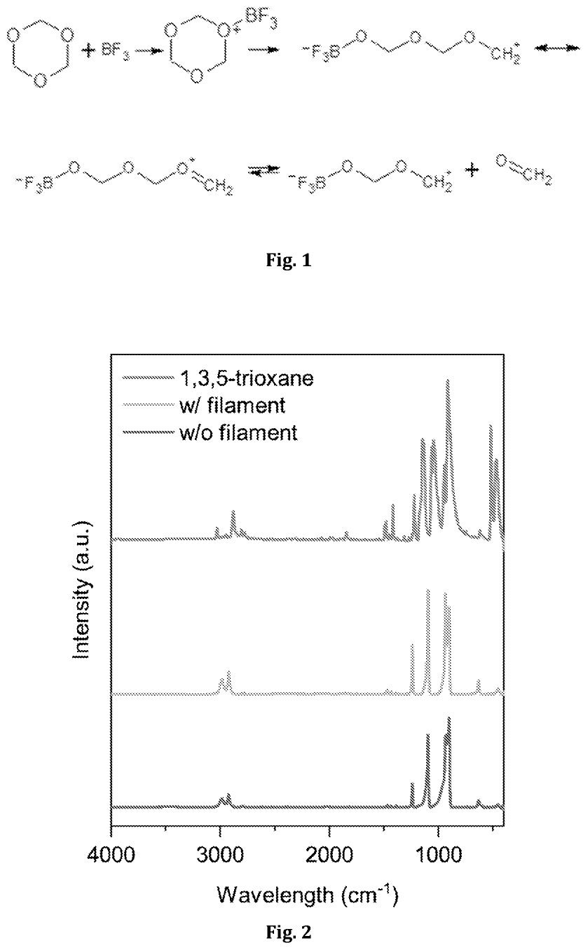

A range of iCVD processing conditions were studied to understand the growth window for iCVD POM, as shown in Table 1. In general, POM grows at sufficiently high z conditions, i.e. where there is sufficient surface monomer concentration. Specifically, this is typically at higher pressures, lower substrate temperatures, and less dilution with lower nitrogen flow rates. At such conditions, deposition rates can range from 80 nm/min to 1 μm/min, with higher growth rates at higher z. Previous studies have reported that trioxane tend to polymerize during gas-solid and liquid-solid phase transitions,¹²⁻¹³ and it is reasonable to suspect that the iCVD polymerization took place only when the monomer adsorbed on the substrate at high enough monomer concentrations. In addition, an induction period is typically observed in the cationic polymerization of 1,3,5-trioxane in solution. In this induction period, formaldehyde and its oligomers form after initiation prior to the formation of macromolecules, and polymerization begins only when formaldehyde reaches a temperature-dependent ceiling concentration that then pushes the reaction equilibrium towards POM formation.¹⁴ It is likely that a similar mechanism can occur in iCVD POM, see FIG. 1, so that sufficiently high z or monomer conditions push the reactions towards POM growth rather than small molecule or oligomer formation that do not yield a solid material. In addition, the POM reaction can be further influenced by the presence of a co-reactant, typically a protogen, that can aid in polymer chain initiation. The protogen can, for example, be water or an alcohol. Thus, reactions with methanol have also been performed as shown in Table 1. In addition, to push the equilibrium towards generating more POM rather than formaldehyde, it is also possible to artificially introduce a formaldehyde vapor environment during the POM reaction. This can be achieved by introducing a flow of formaldehyde vapor from the thermal decomposition of paraformaldehyde. Reactions with formaldehyde have also been performed, as shown in Table 1. The proposed reaction mechanism for the reaction is shown in FIG. 1.

TABLE 1
iCVD processing conditions for POM polymerization.

| | Initiator | Monomer | Nitrogen | Methanol | Formaldehyde | Substrate | | |
|---|---|---|---|---|---|---|---|---|
| | Flowrate | Flowrate | Flowrate | Flowrate | Flowrate | Temperature | Pressure | |
| Run # | (sccm) | (sccm) | (sccm) | (sccm) | (sccm) | (° C.) | (torr) | Filament |
| 1 | 1 | 10 | 0 | 0 | 0 | 16 | 3 | No |
| 2 | 1 | 3 | 0 | 0 | 0 | 16 | 3 | No |
| 3 | 2 | 3 | 0 | 0 | 0 | 21 | 3 | Yes |
| 4 | 1 | 3 | 1 | 0 | 0 | 21 | 3 | Yes |
| 5 | 1 | 10 | 0 | 0 | 0 | 25 | 3 | Yes |
| 6 | 1 | 3 | 1 | 0 | 0 | 21 | 2 | Yes |
| 7 | 1 | 3 | 0 | 0 | 0 | 25 | 3 | Yes |
| 8 | 1 | 3 | 1 | 0 | 0 | 25 | 3 | Yes |
| 9 | 1 | 3 | 1 | 0 | 0 | 21 | 1 | Yes |
| 10 | 1 | 3 | 1 | 0 | 0 | 29 | 3 | Yes |
| 11 | 1 | 3 | 1 | 0 | 0 | 31 | 1 | Yes |
| 12 | 1 | 3 | 0 | 0 | 0 | 11 | 1.25 | No |
| 13 | 1 | 3 | 0 | 0 | 0 | 8 | 1.25 | No |
| 14 | 1 | 3 | 0 | 0 | 0 | 5 | 1.25 | No |
| 15 | 0.85 | 3 | 0.15 | 0 | 0 | 8 | 1.25 | No |
| 16 | 0.70 | 3 | 0.30 | 0 | 0 | 8 | 1.25 | No |
| 17 | 0.85 | 3 | 0.15 | 0 | 0 | 8 | 1.25 | No |
| 18 | 1 | 2 | 1 | 0 | 0 | 8 | 1.25 | No |
| 19 | 1 | 1 | 2 | 0 | 0 | 8 | 1.25 | No |
| 20 | 1 | 3 | 0 | 0 | 0 | 8 | 1.10 | No |
| 21 | 1 | 3 | 0 | 0 | 0 | 8 | 1.40 | No |
| 22 | 0.70 | 3 | 0 | 0.30 | 0 | 8 | 1.25 | No |
| 23 | 1 | 3 | 0 | 1.00 | 0 | 20 | 1.25 | No |
| 24 | 1 | 3 | 0 | 1.00 | 0 | 18.5 | 1.25 | No |
| 25 | 1 | 3 | 0 | 0 | 1.00 | 8 | 1.25 | No |
| 26 | 1 | 3 | 0 | 1.00 | 0 | 8 | 1.25 | No |
| 27 | 1 | 3 | 1 | 0 | 0 | 8 | 1.25 | No |
| 28 | 1 | 0 | 0 | 9.00 | 0 | 8 | 1.25 | No |
| 29 | 0.7 | 3 | 0 | 0.30 | 0 | 8 | 1.25 | No |
| 30 | 0.5 | 3 | 0.50 | 0.30 | 0 | 8 | 1.25 | No |

The data for runs 12-30 were similar to the data provided herein for runs 1-12.

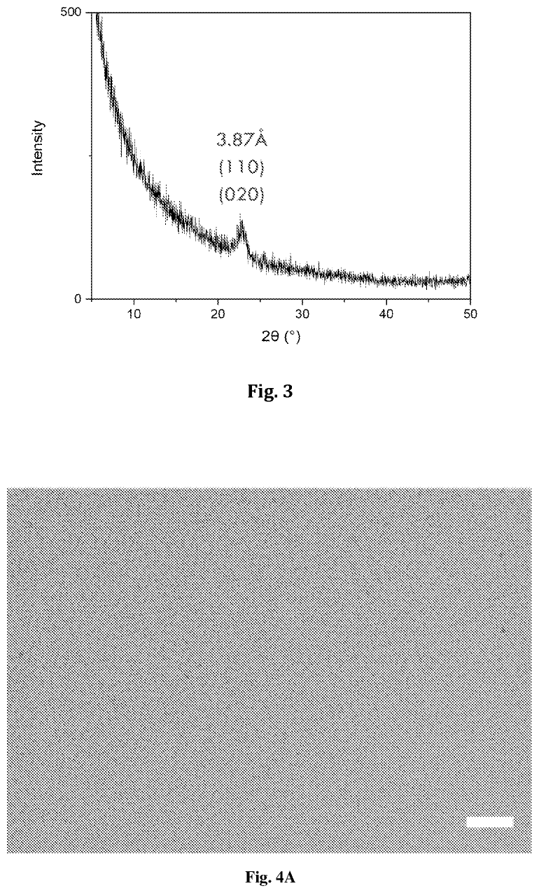

FIG. 2 shows the FTIR spectra of the 1,3,5-trioxane monomer and iCVD POM films deposited with and without a heated filament. The peaks at 2983 and 2923 cm⁻¹ are CH₂ stretching, the 1470, 1383 and 1292 cm⁻¹ peaks are CH₂ bending, wagging and twisting, and 1239, 1095 and 902 cm⁻¹ peaks are C—O—C stretching that are characteristic of POM.⁷ Unlike POM, the monomer has more peaks from 2700 to 3100 cm⁻¹, and strong peaks around 700 to 8000 cm⁻¹ that disappear when polymerized.⁷ FTIR confirms the linear structure and synthesis of POM via iCVD. Also, the FTIR indicates that the POM is primarily in the extended-chain crystal structure form. In addition to FTIR, XRD shows a peak at 22.9° as seen in FIG. 3. This peak yields a reciprocal scattering vector q of 16.2 nm⁻¹ and a d-spacing of 3.87 Å, which represent the (110) and (020) planes of the hexagonal arrays of the trigonal form of POM, which is very close to the theoretical value (3.86 Å).¹⁵

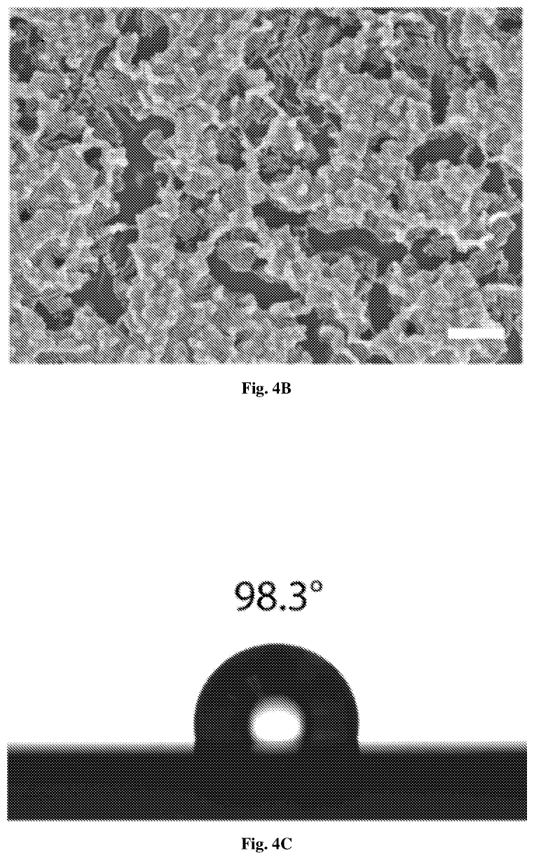

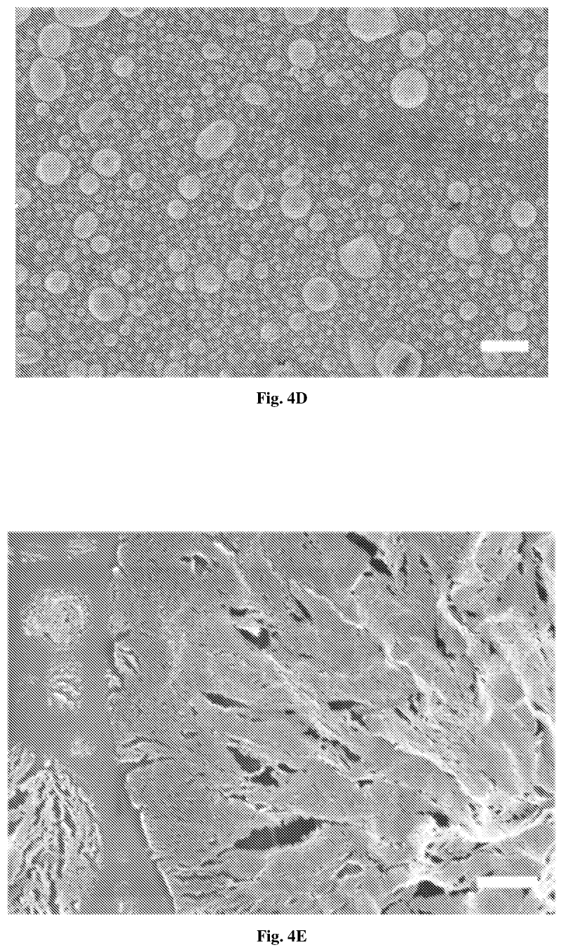

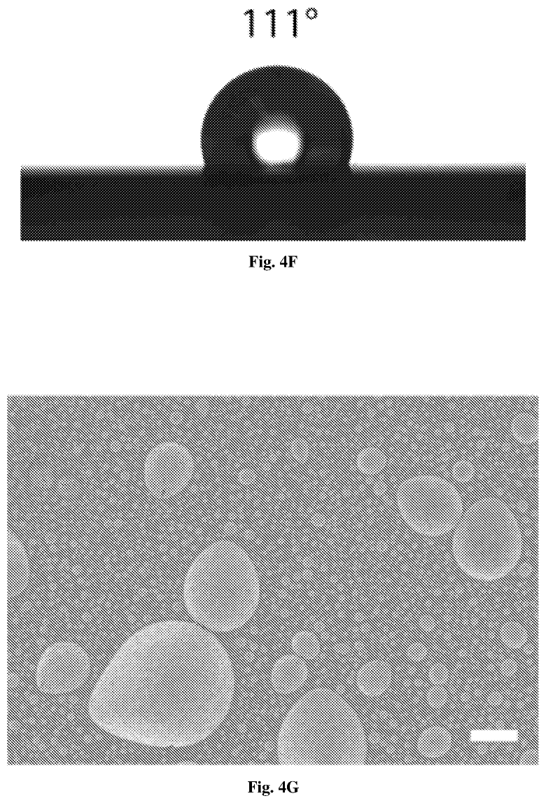

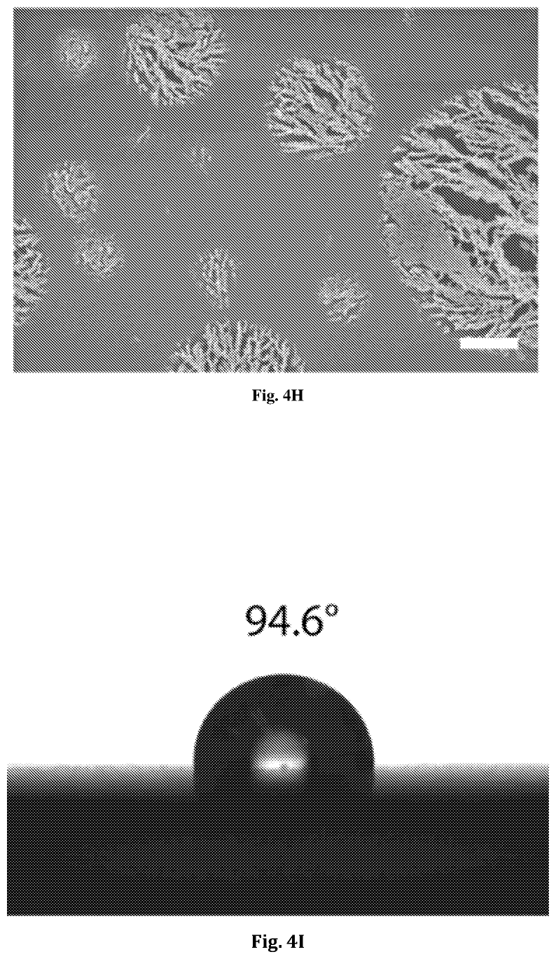

SEM images in FIGS. 4A-4B, 4D-4E, and 4G-4H reveal that the iCVD depositions result in structured POM films, which are likely caused by crystallization during the polymerization process. The introduction of nitrogen and higher substrate temperature both lead to a morphology which has a lot of polymer cluster islands. Such structured films then translate to a more hydrophobic POM surface (water contact angles>90°), which is unlike bulk POM that is reported in literature to be hydrophilic (water contact angle=74.5°<90°).¹⁶ From our process studies, the POM film from run #5 has the largest amount of polymer structures that lead to the highest contact angle of 111°.

For reactions with methanol and/or paraformaldehyde, FTIR also confirms that POM has been deposited. In addition, methanol raised the ceiling temperature for POM deposition, leading to stable growth at higher substrate temperatures. while paraformaldehyde improved deposition uniformity across the whole substrate.

3. Conclusions

POM is successfully synthesized via iCVD by using 1,3,5-trioxane monomer and boron trifluoride initiator. The iCVD POM films are structured that lead to a hydrophobic POM surface. By tuning iCVD process conditions of substrate temperature, reactor pressure, and nitrogen flow, polymer growth, kinetics and morphologies can be adjusted. The ease of dry synthesis and structuration of POM films using the present method can open up new areas of applications, including electronics, mechanical systems, barrier films, templating and advanced composites. Other embodiments of the present disclosure will be apparent to those skilled in the art from consideration of the specification and practice of the embodiments disclosed herein. As used throughout the specification and claims, “a” and/or “an” may refer to one or more than one. Unless otherwise indicated, all numbers expressing quantities of ingredients, properties such as molecular weight, percent, ratio, reaction conditions, and so forth used in the specification and claims are to be understood as being modified in all instances by the term “about,” whether or not the term “about” is present. Accordingly, unless indicated to the contrary, the numerical parameters set forth in the specification and claims are approximations that may vary depending upon the desired properties sought to be obtained by the present disclosure. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in their respective testing measurements. It is intended that the specification and examples be considered as exemplary only, with a true scope and spirit of the disclosure being indicated by the following claims.

The foregoing embodiments are susceptible to considerable variation in practice. Accordingly, the embodiments are not intended to be limited to the specific exemplifications set forth hereinabove. Rather, the foregoing embodiments are within the spirit and scope of the appended claims, including the equivalents thereof available as a matter of law. Other suitable modifications and adaptations of the variety of conditions and parameters normally encountered in the field, and which are obvious to those skilled in the art, are within the scope of the disclosure.

All patents and publications cited herein are fully incorporated by reference herein in their entirety or at least for the portion of their description for which they are specifically cited or relied upon in the present description.

The patentees do not intend to dedicate any disclosed embodiments to the public, and to the extent any disclosed modifications or alterations may not literally fall within the scope of the claims, they are considered to be part hereof under the doctrine of equivalents.

It is to be understood that each component, compound, substituent or parameter disclosed herein is to be interpreted as being disclosed for use alone or in combination with one or more of each and every other component, compound, substituent or parameter disclosed herein.

It is also to be understood that each amount/value or range of amounts/values for each component, compound, substituent or parameter disclosed herein is to be interpreted as also being disclosed in combination with each amount/value or range of amounts/values disclosed for any other component(s), compounds(s), substituent(s) or parameter(s) disclosed herein and that any combination of amounts/values or ranges of amounts/values for two or more component(s), compounds(s), substituent(s) or parameters disclosed herein are thus also disclosed in combination with each other for the purposes of this description.

It is further understood that each range disclosed herein is to be interpreted as a disclosure of each specific value within the disclosed range that has the same number of significant digits. Thus, a range of from 1-4 is to be interpreted as an express disclosure of the values 1, 2, 3 and 4.

It is further understood that each lower limit of each range disclosed herein is to be interpreted as disclosed in combination with each upper limit of each range and each specific value within each range disclosed herein for the same component, compounds, substituent or parameter. Thus, this disclosure to be interpreted as a disclosure of all ranges derived by combining each lower limit of each range with each upper limit of each range or with each specific value within each range, or by combining each upper limit of each range with each specific value within each range.

Furthermore, specific amounts/values of a component, compound, substituent or parameter disclosed in the description or an example is to be interpreted as a disclosure of either a lower or an upper limit of a range and thus can be combined with any other lower or upper limit of a range or specific amount/value for the same component, compound, substituent or parameter disclosed elsewhere in the application to form a range for that component, compound, substituent or parameter.

### References

The following references may be useful in understanding some of the principles discussed herein:

1. Mülhaupt, R., Hermann Staudinger and the origin of macromolecular chemistry. Angewandte Chemie International Edition 2004, 43 (9), 1054-1063.

2. Staudinger, H., Macromolecular Chemistry. In Nobel Lecture, 1953.

3. Baranowski, C. J.; Bahmanpour, A. M.; Kröcher, O., Catalytic synthesis of polyoxymethylene dimethyl ethers (OME): A review. Applied Catalysis B: Environmental 2017, 217, 407-420.

4. Evans, S. M.; Keogh, P. S., Wear mechanisms in polyoxymethylene spur gears. Wear 2019, 428-429, 356-365.

5. Kongkhlang, T.; Tashiro, K.; Kotaki, M.; Chirachanchai, S., Electrospinning as a New Technique To Control the Crystal Morphology and Molecular Orientation of Polyoxymethylene Nanofibers. Journal of the American Chemical Society 2008, 130 (46), 15460-15466.

6. Liu, D.; Zhang, S.; Cheng, H.; Peng, R.; Luo, Z., Thermally Triggered Vanishing Bulk Polyoxymethylene for Transient Electronics. Scientific Reports 2019, 9 (1), 18107.

7. Loo, L. S.; Gleason, K. K., Hot filament chemical vapor deposition of polyoxymethylene as a sacrificial layer for fabricating air gaps. Electrochemical and Solid-State Letters 2001, 4 (11), G81-G84.

8. Lau, K. K.; Gleason, K. K., Initiated chemical vapor deposition (iCVD) of poly (alkyl acrylates): a kinetic model. Macromolecules 2006, 39 (10), 3695-3703.

9. Lau, K. K.; Gleason, K. K., Initiated chemical vapor deposition (iCVD) of poly (alkyl acrylates): an experimental study. Macromolecules 2006, 39 (10), 3688-3694.

10. Bose, R. K.; Nejati, S.; Stufflet, D. R.; Lau, K. K. S., Graft Polymerization of Anti-Fouling PEO Surfaces by Liquid-Free Initiated Chemical Vapor Deposition. Macromolecules 2012, 45 (17), 6915-6922.

11. Hsieh, C.-Y.; Lau, K. K. S., Growth of Polyglycidol in Porous TiO2 Nanoparticle Networks via Initiated Chemical Vapor Deposition: Probing Polymer Confinement Under High Nanoparticle Loading. Advanced Materials Interfaces 2015, 2 (17), 1500341-n/a.

12. Hammick, D. L.; Boeree, A. R., CCCXXIX.—Preparation of α-trioxymethylene and a new polymeride of formaldehyde. Journal of the Chemical Society, Transactions 1922, 121, 2738-2740.

13. Weissermel, K.; Fischer, E.; Gutweiler, K.; Hermann, H.; Cherdron, H., Polymerization of trioxane. Angewandte Chemie International Edition in English 1967, 6 (6), 526-533.

14. Kern, W.; Jaacks, V., Some kinetic effects in the polymerization of 1,3,5-trioxane. Journal of Polymer Science 1960, 48 (150), 399-404.

15. Carazzolo, G.; Mammi, M., Crystal structure of a new form of polyoxymethylene. Journal of Polymer Science Part A: General Papers 1963,1 (3), 965-983.

16. Kaelble, D.; Cirlin, E., Dispersion and polar contributions to surface tension of poly (methylene oxide) and Na-treated polytetrafluoroethylene. Journal of Polymer Science Part A-2: Polymer Physics 1971, 9 (2), 363-368.

1. A method for synthesizing polyoxymethylene on a substrate, comprising a step of:
depositing a monomer capable of forming polyoxymethylene by an initiated polymerization reaction and an initiator, via initiated chemical vapor deposition (iCVD) onto a surface of a substrate in an initiated chemical vapor deposition reactor.

2. The method of claim 1, wherein the substrate is cooled to a temperature to promote deposition of the monomer and initiator on the substrate.

3. The method of claim 2, wherein the substrate is cooled to a temperature of from about 0° C. to about 50° C.

4. The method of claim 1, wherein an internal reactor pressure in the initiated chemical vapor deposition reactor is from about 0.1 to about 10 torr, as measured using a pressure gauge, e.g. capacitance manometer.

5. The method of claim 1, wherein the depositing step is carried out at a flow rate of monomer to the initiated chemical vapor deposition reactor of from about 0.1 to about 20 standard cubic centimeter per minute.

6. The method of claim 1, wherein the initiator is selected from the group consisting of boron trifluoride diethyl etherate, boron trifluoride, and other boron trifluoride complexes, including boron trifluoride complexed with water, phenol, acetic acid, tetrahydrofuran, methanol, propanol, ethylamine, methyl sulfide and dibutyl ether.

7. The method of claim 1, wherein the initiator is heated to a temperature of from 30° C. to 50° C. prior to feeding the initiator to the initiated chemical vapor deposition reactor.

8. The method of claim 1, wherein the initiator is fed to the initiated chemical vapor deposition reactor at a flow rate of from about 0.1 to 10 standard cubic centimeter per minute.

9. The method of claim 1, wherein the substrate is selected from silicon, glass, fabrics, paper, plastics, pharmaceuticals, metals, metal oxides, ionic liquids, and surfaces and devices that comprise one or more of structured, templated, machined, and defined topologies.

10. The method of claim 1, wherein the depositing step is carried out with one or more heated filaments located in the initiated chemical vapor deposition reactor.

11. The method of claim 10, wherein the one or more filaments is a phosphor bronze filament wire.

12. The method of claim 10, wherein the filament is heated to a temperature of from 150° C. to 400° C.

13. The method of claim 1, wherein the method further comprises a step of introducing nitrogen gas into the reactor.

14. The method of claim 13, wherein the nitrogen gas is introduced into the reactor at a flow rate of from 0.1 standard cubic centimeter per minute to about 2 standard cubic centimeter per minute.

15. The method of claim 1, wherein the monomer is selected from the group consisting of 1,3,5-trioxane, formaldehyde, dioxane, other ring molecules that can form formaldehyde and its oligomers such as larger (CH₂O) ring-containing molecules, and other monomers known for use in polymerization reactions to form polyoxymethylene.

16. The method of claim 1, wherein the depositing step is carried out under conditions such that the fractional saturation (Z_{M}) of the 1,3,5-trixoane monomer at the substrate surface is between 0.1 to about 1, wherein Z_{M} is defined by the following expression:
$${z}_{M} = \frac{{P}_{M}}{{P}_{M , sat}} ,$$
wherein P_{M} is the partial pressure in the gas phase of the monomer, as calculated based on component flow rates metered through precision needle valves or mass flow controllers and reactor total pressure as measured through a pressure gauge, and P_{M,sat} is the vapor pressure of the monomer at the substrate surface, based on the equilibrium vapor pressure data of the monomer at the substrate temperature as measured by a surface temperature probe.

17. The method of claim 1, wherein the method further comprises a step of introducing one or more co-reactants selected from water, alcohols, and aldehydes.

18. The method of claim 17, wherein the co-reactant is methanol and the methanol is introduced into the reactor at a flow rate of from about 0.1 standard cubic centimeter per minute to about 2 standard cubic centimeter per minute.

19. The method of claim 17, wherein the co-reactant is paraformaldehyde and the paraformaldehyde is heated to 60° C.- 120° C. and provided at a vapor flow rate of from about 0.1 standard cubic centimeter per minute to about 2 standard cubic centimeter per minute.

20. The method of claim 1 , wherein the method further comprises a step of introducing water.
